(19) United States
(12) Patent Application Publication
(10) Pub. No.: US 2026/0149443 A1
(43) Pub. Date: May 28, 2026

(54) SMART TIME CONTROL FOR SWITCHING AMONG VARIOUS PHASES OF A DEVICE VIA A SINGLE CAPACITOR

(71) Applicant: TEXAS INSTRUMENTS INCORPORATED, Dallas, TX (US)

(72) Inventors: Ding Yan, Shanghai (CN); Xingkai Zhou, Changzhou (CN)

(21) Appl. No.: 18/956,662

(22) Filed: Nov. 22, 2024

(51) Int. Cl. H03K 5/24; H03K 3/037

(52) U.S. Cl. CPC H03K 5/249; H03K 3/0375

(57) ABSTRACT

An apparatus includes a first current source configured to provide a first bias current and a second current source configured to provide a second bias current, wherein the first bias current is larger than the second bias current. The apparatus further includes a current switch configured to receive the first bias current and the second bias current at its two input terminals and provide an output current at an output terminal, wherein the output current is one of the first bias current and the second bias current selected by a current switch control signal to the current switch. The apparatus further includes a capacitor coupled between the output terminal and a ground terminal, wherein the capacitor is charged by the output current and provides an output voltage at the output terminal.

### BACKGROUND

Time control is important for various phases of a device (e.g., a switching regulator). Specifically, after the regulator is powered up (a power up phase), the regular enters a system enable (sys-en) phase, in which the time delay is around one hundred microseconds as the device waits for its internal power supply to be settled. The sys-en phase is followed by a soft-start (SS) phase, in which the time typically lasts for milliseconds in order to provide a smooth output voltage (Vout). Due to such timing differences, time control of the sys-en phase and the SS phase is traditionally handled by separate timing generation circuitries. For example, the delay for the sys-en phase can be generated by a digital counter comprised of multiple D-flips while time for the SS phase can be generated by charging a capacitor. Additionally, extra analog control circuitry is often required to separate between the sys-en phase and the SS phase. These redundant circuitries often result in large chip size overhead and waste for the device.

### SUMMARY

In an example, an apparatus includes a first current source configured to provide a first bias current and a second current source configured to provide a second bias current, wherein the first bias current is larger than the second bias current. The apparatus further includes a current switch configured to receive the first bias current and the second bias current at its two input terminals and provide an output current at an output terminal, wherein the output current is one of the first bias current and the second bias current selected by a current switch control signal to the current switch. The apparatus further includes a capacitor coupled between the output terminal and a ground terminal, wherein the capacitor is charged by the output current and provides an output voltage at the output terminal.

In another example, a method includes providing a first bias current via a first current source and providing a second bias current via a second current source, wherein the first bias current is larger than the second bias current. The method further includes receiving the first bias current and the second bias current at two input terminals of a current switch and providing an output current at an output terminal of the current switch, wherein the output current is one of the first bias current and the second bias current selected by a current switch control signal to the current switch. The method further includes charging a capacitor coupled between the output terminal and a ground terminal by the output current and providing an output voltage at the output terminal.

### BRIEF DESCRIPTION OF THE DRAWINGS

FIG. 1 is a schematic diagram of a system of time control for switching among various phases of a device, in an example.

FIG. 2 is a graph illustrating waveforms of multiple signals of FIG. 1 switching among various phases, in an example.

FIG. 3A is a graph illustrating waveforms of the output voltage SS_INT and the comparison output signal DONE during the hiccup protection phase; FIG. 3B is a schematic diagram of a time control circuitry used during the hiccup current protection mode, in an example.

FIG. 4A is a graph illustrating waveforms related to clock dithering and FIG. 4B is a schematic diagram of a clock ditching circuitry, in an example.

### DETAILED DESCRIPTION

The same reference numbers or other reference designators are used in the drawings to designate the same or similar (either by function and/or structure) features.

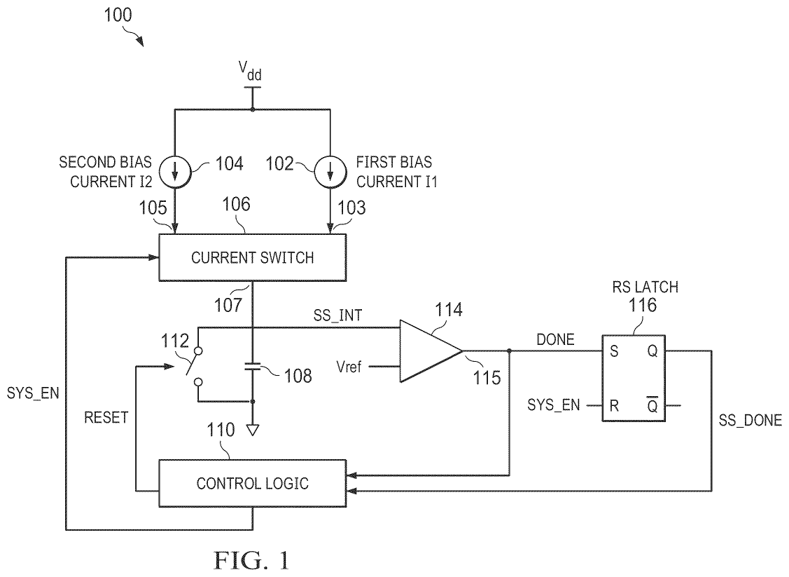

FIG. 1 is a schematic diagram of an illustrative example of a system 100 of time control for switching among various phases of a device. As shown in the example of FIG. 1, the system 100 includes a first current source 102 configured to provide a first bias current I1 and a second current source 104 configured to provide a first bias current I2. In one example, the first bias current I1 is larger than the second bias current I2. The system 100 further includes a current switch 106, which is configured to receive the first bias current I1 from the first current source 102 and the second bias current I2 from the second current source 104 at its two input terminals 103 and 105, respectively. The current switch 106 is configured to provide an output current at an output terminal 107, wherein the output current is one of the first bias current and the second bias current as selected by a current switch control signal SYS_EN to the current switch 106. The current switch control signal SYS_EN to the current switch 106 toggles between the first bias current I1 and the second bias current I2, wherein the first bias current I1 is larger and faster charging than the second bias current I2. The system 100 further includes a single capacitor 108 coupled between the output terminal 107 and a ground terminal. During operation, the capacitor 108 is charged by the output current-one of the first bias current I1 and the second bias current I2—from the current switch 106, and the capacitor 108 provides an output voltage SS_INT at the output terminal 107.

The system 100 as shown in FIG. 1 uses only a single capacitor 108 to create different time/delay types and thus removes redundant time control logic (e.g., digital counters and other digital and/or analog circuitries) as well as extra capacitors needed by a clock. As a result, the system 100 reduces chip area and cost. By toggling between different bias currents I1 and I2 via a single current switch 106, the system 100 controls charging time of the single capacitor 108 to be either large (e.g., ms) with a small bias current I2 or small (e.g., μs) with a large bias current I1 for different switching phases of the device, respectively. As such, the traditionally separated time control circuitry for the sys-en and SS phases of the device can be integrated into one circuitry as discussed in detail below.

In one example, the system 100 further includes a discharge switch 112 coupled between the output terminal 107 and the ground terminal, wherein the discharge switch 112 is controlled by a discharge/reset signal. When the discharge switch 112 is turned off by the discharge signal, the output voltage SS_INT maintains at its current level. When the discharge switch 112 is turned on by the discharge signal, the output terminal 107 connects to the ground terminal and discharges the capacitor 108, resetting the output voltage SS_INT to low or 0.

In one example, the system 100 further includes a voltage comparator 108 configured to receive the output voltage SS_INT and a reference voltage Vref as its two inputs and provide a comparison output voltage/signal DONE at its comparison output terminal 115 based on a comparison between the output voltage SS_INT and the reference voltage Vref. In one example, the comparison output signal DONE remains at low when the output voltage SS_INT is less than the reference voltage Vref. The comparison output signal DONE becomes high when the output voltage SS_INT is equal to the reference voltage Vref.

In one example, the system 100 further includes a reset (RS) latch 116 configured to receive the comparison output signal DONE and the current switch control signal SYS_EN as its two inputs S and R, respectively, and generate a latch output signal SS_DONE for a certain period of time. In one example, the reset (RS) latch 116 sets the latch output signal SS_DONE to high based on the comparison output signal DONE and resets the latch output signal SS_DONE to low based on the current switch control signal SYS_EN.

In one example, the system 100 further includes a control logic unit 110 configured to receive the comparison output signal DONE and the latch output signal SS_DONE as its inputs, and generate the current switch control signal SYS_EN to the current switch 106 to toggle between the first bias current I1 and the second bias current I2 as the output current from the current switch 106. In an example, the current switch control signal SYS_EN generated by the control logic unit 110 is an analog time control signal that separates various different phases of the device, e.g., powerup phase and the system enable phase. In one example, the control logic unit 110 is configured to utilize a finite state machine to control the transition among the various phases represented by states of the finite state machine and to avoid various kinds of fault reset conditions via the current switch control signal SYS_EN.

In one example, the control logic unit 110 is configured to generate the discharge signal to turn the discharge switch 112 on or off to respectively reset or maintain the output voltage SS_INT at output voltage terminal 107. In one example, a set of periodic pulses of the comparison output signal DONE is served as a reset signal for discharging the capacitor 108. The control logic unit 110 is configured to count the number of periodic pulses of the comparison output signal DONE in the set to determine when to discharge the capacitor 108.

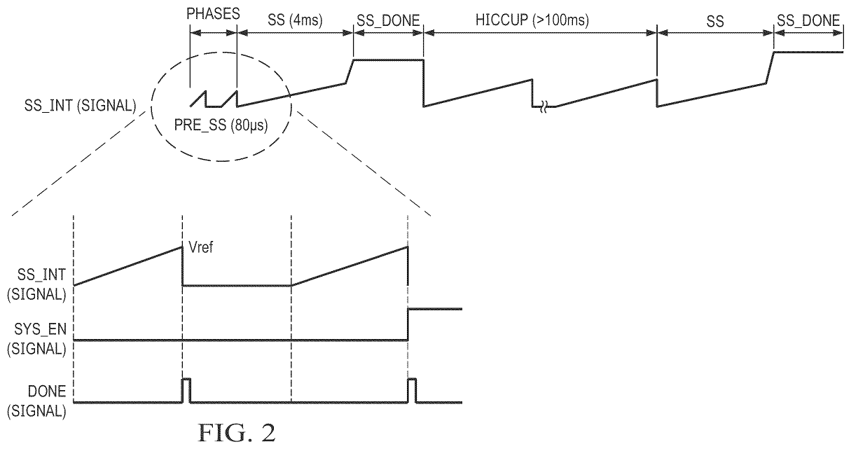

FIG. 2 is a graph illustrating examples of waveforms of multiple signals of FIG. 1 switching among various phases. As shown by FIG. 2, the current switch control signal SYS_EN is low initially, which selects the large bias current I1 as the output current during the pre_SS (or sys-en) phase. The output voltage SS_INT ramps up quickly and linearly when the capacitor 108 is being charged quickly by the large bias current I1 during the pre_SS phase until the output voltage SS_INT reaches the reference voltage Vref. At that point in time, the voltage comparator 108 sets the comparison output signal DONE as high, causing the control logic unit 110 to send the discharge signal to turn the discharge switch 112 on to discharge the capacitor 108. Once the capacitor 108 is discharged, the output voltage SS_INT falls back to low, which lowers the comparison output signal DONE to low as well and creates a pulse in the comparison output signal DONE. After detecting and counting one or more of such pulses in the comparison output signal DONE, e.g., two pulses as shown in FIG. 2, the control logic unit 110 turns the current switch control signal SYS_EN to high. As shown by the example of FIG. 2, each quick charging cycle of the capacitor 108 takes about 40 μs. As such, the current switch control signal SYS_EN provides about 80 us of delay for the system enable phase over two quick charging cycles.

When the current switch control signal SYS_EN becomes high, the output current form the current switch 106 is toggled from the large bias current I1 to the small bias current I2, and the capacitor 108 entering a slow charging phase, e.g., the SS phase, during which the output voltage SS_INT slowly and linearly ramps up. As shown by the example of FIG. 2, the slow charging SS phase may last about 4 ms until the output voltage SS_INT reaches the reference voltage Vref. At this time, instead of resetting the output voltage SS_INT, the control logic unit 110 may hold the output voltage SS_INT at a high level over a certain period time during the SS_DONE phase as shown by FIG. 2 based on the latch output signal SS_DONE. Here, the latch output signal SS_DONE is generated by the reset latch 116 based on the comparison output signal DONE and the current switch control signal SYS_EN.

In one example, the output voltage SS_INT generated by the system 100 can be used (e.g., multiplexed) to meet time requirements of additional phases and/or applications other than sys-en and SS phases discussed above. For non-limiting examples, the output voltage SS_INT can also be used for time control of hiccup protection and dithering phases/modes/features following the SS_DONE phase. In the case of the hiccup mode caused sustained short or faulty conditions, a hiccup protection phase is activated in order to shut down the device for a certain period of hiccup time (T_hiccup), e.g., 88 ms.

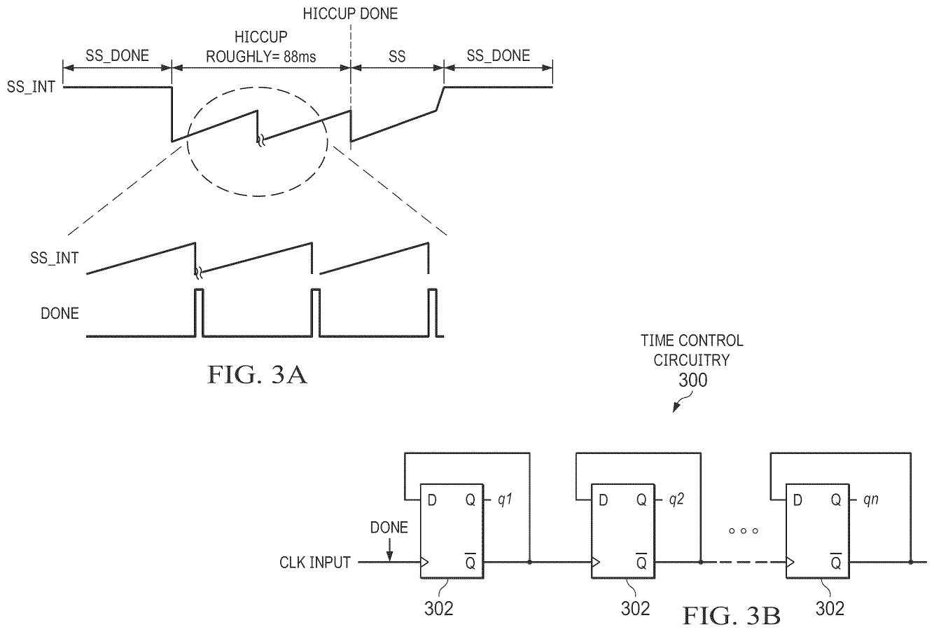

FIG. 3A is a graph illustrating examples of waveforms of the output voltage SS_INT and the comparison output signal DONE during the hiccup protection phase and FIG. 3B is a schematic diagram of an illustrative example of a time control circuitry 300 used during the hiccup current protection mode.

As shown by the example of FIG. 3A, the hiccup protection phase may include a plurality of slow charging cycles, each including a slow ramp up and subsequent reset of the output voltage SS_INT, which result in a set of periodic pulses in the comparison output signal DONE as the slow charging SS cycles discussed above. The set of periodic pulses in the comparison output signal DONE is then used as a clock input to the time control circuitry 300, which can be a digital counter comprising a plurality of D-flips 302s connected in series as shown in FIG. 3B. In one example, the set of periodic pulses of the comparison output signal DONE is selected/multiplexed from multiple clock sources. In one example, the number of D-flips 302s in the time control circuitry 300 is determined flexibly by the hiccup time needed. For a nonlimiting example, if each slow charging cycle is 4 ms, it needs 22 slow charging cycles and a corresponding number of D-flips 302s to obtain 88 ms hiccup time.

In the case of clock dithering, a dithering current I_{dither} is created by inserting a triangular current source I₁ into or extracting the triangular current source I₁ from an oscillating current lose, wherein the dithering current I_{dither} is utilized to generate a clock with a frequency f triangular dithering within a certain frequency range (fmin, fmax) according to the following equation:

$$f = \frac{{I}_{dither}}{{CV}_{ref}} = \frac{{I}_{osc} \pm {I}_{1}}{{CV}_{ref}}$$

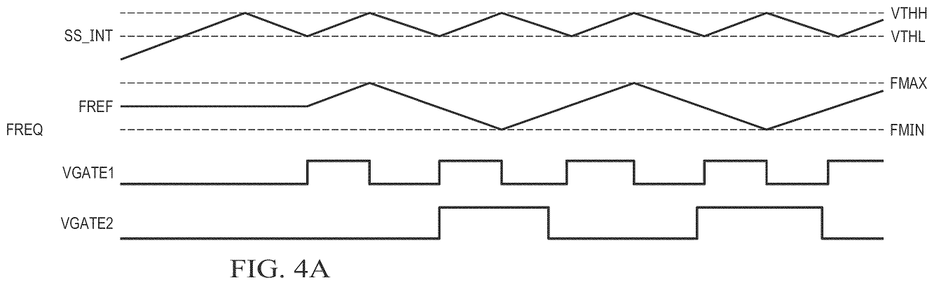

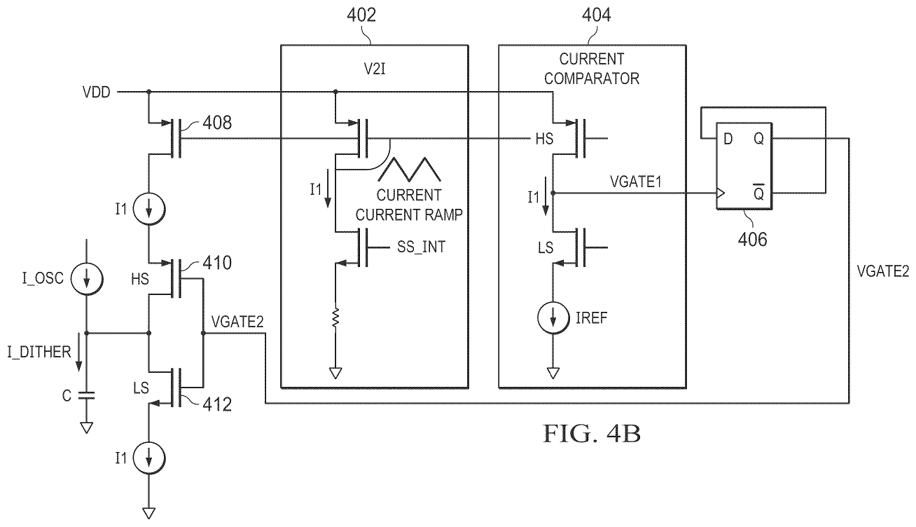

FIG. 4A is a graph illustrating examples of waveforms related to clock dithering and FIG. 4B is a schematic diagram of an illustrative example of a clock ditching circuitry 400. The output voltage SS_INT generated by the system 100 is a ramp signal but, as shown by FIG. 4A, it can be further shaped by the system 100 into a triangular waveform signal modulated linearly between two threshold levels—Vthh and Vth1.—by controlling the discharging and charging currents from cycle to cycle. A voltage-to-current (V2I) conversion circuit 402 shown in FIG. 4B is utilized to convert the triangular waveform of SS_INT into the triangular current source I1, wherein the value of I1 is limited to be within a certain range, Imin (e.g., OA)<I1<Imax (e.g., 37 nA). The triangular current source I1 is then fed into a current comparator 404, which compares I1 with a reference current Iref and generates a first clock switching signal vgate1. In one example, vgate1 is also used as an input to a D-flip 406 to generate a second clock switching signal vgate2 at about half of the frequency of vgate1 as shown in FIG. 4A. The clock switching signals vgate1 and vgate2 are then used to control a set of FETs, e.g., 408, 410, and 412, to generate the dithering current I_{dither} by inserting I₁ into or extracting I₁ from the oscillating current lose, wherein the dithering current I_{dither} is then utilized to generate the dithering clock within the frequency range (fmin, fmax) as follows:
vgate1=1 and vgate2=0: Idither=losc+I1 and the clock frequency f increases to fmax;
vgate1=0 and vgate2=0, Idither=losc+I1 and the clock frequency f decreases to fref;
vgate1=1, and vgate2=1, Idither=losc−I1 and the clock frequency f decreases to fmin;
vgate1=0, and vgate2=1, I_{dither}=losc−I1 and the clock frequency f increases to fref;
   wherein fref is a reference frequency between fmin and fmax as shown in FIG. 4A.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An apparatus comprising:
a first current source configured to provide a first bias current;
a second current source configured to provide a second bias current, wherein the first bias current is larger than the second bias current;
a current switch configured to
receive the first bias current and the second bias current at its two input terminals; and
provide an output current at an output terminal, wherein the output current is one of the first bias current and the second bias current selected by a current switch control signal to the current switch; and
a capacitor coupled between the output terminal and a ground terminal, wherein the capacitor is charged by the output current and provides an output voltage at the output terminal.

2. The apparatus of claim 1, further comprising:
a discharge switch coupled between the output terminal and the ground terminal, wherein the discharge switch is controlled by a discharge signal.

3. The apparatus of claim 2, further comprising:
a voltage comparator configured to
receive the output voltage and a reference voltage as its two inputs; and
provide a comparison output signal based on comparison between the output voltage and the reference voltage.

4. The apparatus of claim 3, further comprising:
a reset latch configured to
receive the comparison output signal and the current switch control signal as its inputs; and
generate a latch output signal for a certain period of time based on the comparison output signal and the current switch control signal.

5. The apparatus of claim 4, further comprising:
a control logic unit configured to
receive the comparison output signal and the latch output signal as its inputs; and
generate the current switch control signal to the current switch to select one of the first bias current and the second bias current as the output current from the current switch.

6. The apparatus of claim 5, wherein:
the control logic unit is configured to generate the discharge signal to the discharge switch to reset or maintain the output voltage at the output terminal.

7. The apparatus of claim 5, wherein:
the control logic unit is configured to control the output voltage for a system enable phase of a device by selecting the first bias current to charge the capacitor via the current switch control signal.

8. The apparatus of claim 5, wherein:
the control logic unit is configured to control the output voltage for a soft start phase of a device by selecting the second bias current to charge the capacitor via the current switch control signal.

9. The apparatus of claim 5, wherein:
the control logic unit is configured to control the output voltage for a hiccup protection phase of a device, wherein the output voltage is used to generate a clock signal over a plurality of slow charging cycles.

10. The apparatus of claim 5, wherein:
the control logic unit is configured to control the output voltage for clock dithering, wherein the output voltage is utilized to generate a clock with a frequency triangular dithering within a certain frequency range.

11. A method, comprising:
providing a first bias current via a first current source;
providing a second bias current via a second current source, wherein the first bias current is larger than the second bias current;
receiving the first bias current and the second bias current at two input terminals of a current switch;
providing an output current at an output terminal of the current switch, wherein the output current is one of the first bias current and the second bias current selected by a current switch control signal to the current switch;
charging a capacitor coupled between the output terminal and a ground terminal by the output current and;
providing an output voltage at the output terminal.

12. The method of claim 11, further comprising:
discharging the capacitor via a discharge switch coupled between the output terminal and the ground terminal, wherein the discharge switch is controlled by a discharge signal.

13. The method of claim 12, further comprising:
receiving the output voltage and a reference voltage as two inputs to a voltage comparator; and
providing a comparison output signal based on comparison between the output voltage and the reference voltage.

14. The method of claim 13, further comprising:
receiving the comparison output signal and the current switch control signal as inputs to a reset latch; and
generating a latch output signal for a certain period of time based on the comparison output signal and the current switch control signal.

15. The method of claim 14, further comprising:
receiving the comparison output signal and the latch output signal as inputs to a control logic; and
generating the current switch control signal to the current switch to select one of the first bias current and the second bias current as the output current from the current switch.

16. The method of claim 15, further comprising:
generating the discharge signal to the discharge switch to reset or maintain the output voltage at the output terminal.

17. The method of claim 15, further comprising:
controlling the output voltage for a system enable phase of a device by selecting the first bias current to charge the capacitor via the current switch control signal.

18. The method of claim 15, further comprising:
controlling the output voltage for a soft start phase of a device by selecting the second bias current to charge the capacitor via the current switch control signal.

19. The method of claim 15, further comprising:
controlling the output voltage for hiccup phase of a device, wherein the output voltage is used to generate a clock signal over a plurality of slow charging cycles.

20. The method of claim 15, further comprising:
controlling the output voltage for clock dithering, wherein the output voltage is utilized to generate a triangular clock dithering with a frequency within a certain frequency range.
